(19) United States
(12) Patent Application Publication
(10) Pub. No.: US 2017/0059673 A1
(43) Pub. Date: Mar. 2, 2017

(54) HIGH-PRESSURE, HIGH-TEMPERATURE NMR APPARATUS

(71) Applicant: PERM Instruments Inc., Calgary (CA)

(72) Inventors: APOSTOLOS KANTZAS, Calgary (CA); Serguei I. Krioutchkov, Calgary (CA); Zheng Yin Wang, Calgary (CA)

(73) Assignee: PERM Instruments Inc., Calgary (CA)

(21) Appl. No.: 15/248,441

(22) Filed: Aug. 26, 2016

Related U.S. Application Data
(60) Provisional application No. 62/211,431, filed on Aug. 28, 2015.

(51) Int. Cl. G01R 33/30; G01R 33/46; G01R 33/31

(52) U.S. Cl. CPC G01R 33/305; G01R 33/307; G01R 33/31; G01R 33/46

(57) ABSTRACT

The invention relates to a method and apparatus for characterising samples under high pressure and/or high temperature temperatures using NMR. The apparatus comprises a confined pressure chamber; a NMR coil positioned within the chamber and configured to receive a sample in a sample position inside the NMR coil; and a pressure applicator configured to apply a pressure within the pressure chamber, thereby allowing NMR measurements to be made of a sample in the sample position at the applied pressure and temperature using the NMR coil.

### FIELD

This application is related to systems and methods for high-pressure, high-temperature nuclear magnetic resonance (NMR) spectroscopy. Specifically the system is related to using a confined pressure chamber to apply a pressure to a sample in order to allow NMR measurements at various pressures and temperatures to be made. The systems and methods described herein enable obtaining and analyzing NMR spectra of core or fluid samples.

### BACKGROUND

In the oil and gas industry, production of oil and gas in tight formations is becoming more and more important. The pressures in such formations can reach 10,000 psi (˜70 MPa) and temperatures close to 200° C. The understanding of the physical state of a given fluid (absorbed on the solid surface or liquid/gas in open space of the reservoir pores), the composition of the fluids, and their interactions has been difficult to characterise. The “physical state” may be considered to be a standard term used in thermodynamics: and may include, for example, solid state, liquid state, and gaseous state. Material in open space may often be in gaseous state. The relaxation time of a gas may be long (e.g. in the seconds range). Adsorbed molecules may relax much faster (e.g. tens of milliseconds to microseconds). If adsorption reaches the level when multi-molecule layer is formed the density of the substance in this layer may respond in a similar way to a liquid as the layer is close to the density of this material in liquid state.

In the past, x-ray microtomography and/or microscopy have been used to visualise core samples. However, these approaches are slow and so dynamic response analysis is limited. In the past, high-pressure NMR technology such as is described in U.S. Pat. No. 4,164,700 have focussed on designing a sample tube configured to withstand the desired pressures and to fit inside the NMR coil. This arrangement means that the shape and materials of the tube are a compromise between, for example, the transparency of the tube to NMR signals, the ability of the tube to maintain the conditions within the tube; and the cost of manufacturing the tube. For example, using a conventional plastic tube may allow the NMR signals to be transmitted and may be inexpensive; however, plastic may not allow very high temperatures or pressures to be maintained. As NMR meters use magnetic fields, metallic materials located near NMR meters may undermine the accuracy and sensitivity of the NMR meter.

In addition to the high pressures and/or temperatures, many oil and gas samples may create a corrosive environment as process fluids can typically comprise hydrocarbons, hydrogen sulfide, water, steam, and/or carbon dioxide as well as inert substances such as nitrogen gas and sand particles. Thus, in the context of alternative metering technologies, including NMR equipment, there continues to be a need for effective apparatus for containing a sample that can withstand the corrosive environment of oil and gas related samples (e.g. core samples) as well as the high temperatures and pressures of oil and gas wells while also enabling effective alternative metering.

As a result, there continues to be a need for testing equipment and methodologies, particularly for NMR instruments, that allow for high pressures and/or high temperatures to be applied to a sample.

### SUMMARY

In accordance with the present disclosure, there is provided an NMR apparatus comprising: a confined pressure chamber; a NMR coil positioned within the chamber and configured to receive a sample in a sample position inside the NMR coil; and a pressure applicator configured to apply a pressure within the pressure chamber, thereby allowing NMR measurements to be made of a sample in the sample position at the applied pressure using the NMR coil.

The confined pressure chamber may be sealable.

The NMR apparatus may comprise a heater, the heater being configured to heat the sample.

The NMR apparatus may comprise a cooler, the cooler being configured to cool the sample.

The pressure chamber may comprise at least one duct, the duct configured to allow a fluid to be introduced into and/or removed from the pressure chamber.

The pressure applicator may comprise a pump configured to introduce fluid into the pressure chamber via a duct to thereby pressurize the chamber and the sample. The pressure applicator may comprise a moveable pressurising element configured to reduce the volume inside the confined pressure chamber. For example, the pressurising element may comprise a moveable wall of the confined pressure chamber and/or an expanding element within the confined pressure chamber (e.g. which as the expanding element expands, the internal volume of the chamber is reduced).

A pump may comprise one or more of rotary lobe pump, a progressive cavity pump, a rotary gear pump, a piston pump, a diaphragm pump, a screw pump, a gear pump, a hydraulic pump, a rotary vane pump, a scroll pump, a regenerative (peripheral) pump, a peristaltic pump, a rope pump, a flexible impeller pump

The NMR apparatus may comprise a fluid heater, the fluid heater configured to heat a fluid to be introduced into the pressure chamber via a duct.

The fluid may comprise a gas. The fluid may comprise a liquid. The fluid may comprise a mixture of gas and liquid. The fluid may comprise deuterated water.

The pressure chamber may be cylinder-shaped. The NMR coil axis may be aligned with the axis of the pressure chamber.

The pressure chamber may comprise a conductive inner layer, the conductive inner layer configured to constrain the magnetic field of the NMR coil and to shield the interior of the pressure chamber from external magnetic fields.

The conductive inner layer may comprise metallic copper.

The NMR apparatus may comprise one or more protective layers, the one or more protective layers comprising one or more of: protective material positioned between the NMR coil and the inner surface of the pressure chamber; and protective material positioned between the NMR coil and the sample position. At least one of the protective layers may comprise polyether ether ketone (PEEK).

The NMR apparatus may comprise at least one spacer positioned within the NMR core beside the sample position, the at least one spacer configured to restrict the presence of fluid within the NMR core. The spacer may be configured to allow fluid to reach the sample position.

The spacer may comprise a channel configured to facilitate fluid flow to and from the sample.

The length of sample in the direction of the NMR coil axis may be between about 10 cm (4 inches) and about 50 cm (20 inches). The length of the sample in the direction of the NMR coil axis may be greater than about 1 cm (0.4 inches). The length of the sample in the direction of the NMR coil axis may be less than 10 cm (4 inches).

The NMR apparatus may comprise or form part of an NMR system. The NMR apparatus or system may be configured to apply a CPMG (Car-Purcell-Meiboom-Gill) signal and/or a FID (Free induction decay) signal to the NMR coil.

The NMR apparatus may comprise a one or more of transmitter configured transmit an NMR signal to the NMR coil; a transmission/reception switch for controlling whether the signal generated by the transmitter is sent to the NMR coil and/or how the response is received from the NMR coil; an amplifier configured to process the received response signal; a digital receiver configured to receive and detect the response; a heater controller configured to control a heater (and so control the temperature in the chamber); a flood pump configured to flood the sample with fluid; and an overburden pump configured to apply a pressure inside the chamber.

The NMR apparatus may comprise a controller, the controller configured to control one or more of the following: signals applied to the NMR coil; temperature applied to the sample; pressure applied to the sample; and flow rate of fluid through the sample. The controller may be configured to control various systems including one or more of a transmitter; transmission/reception switch for controlling whether the signal generated by the transmitter is sent to the NMR coil and/or how the response is received from the NMR coil; an amplifier configured to process the received response signal; a digital receiver configured to receive and detect the response; a heater controller configured to control the heater (and so control the temperature in the chamber); a flood pump configured to flood the sample with fluid; and an overburden pump configured to apply a pressure inside the chamber.

The pressure chamber may comprise metallic titanium and/or titanium alloy.

The NMR apparatus may comprise a flexible sample compartment configured: to contain the sample (and flooding fluid) in the sample position; and allow pressure to be transmitted from a conditioning fluid to the sample, the conditioning fluid being outside the flexible sample compartment.

The NMR apparatus may comprise at least one flooding conduit, the flooding conduit configured to enable flooding fluid to flow between the outside of the pressure chamber and the sample.

The NMR apparatus may comprise at least one conditioning conduit, the conditioning conduit configured to enable conditioning fluid to flow between the outside of the pressure chamber and the sample.

According to a further aspect, there is provided a method, the method comprising: positioning a sample within an NMR coil, the NMR coil being positioned within a confined pressure chamber; applying a pressure within the pressure chamber, thereby applying a pressure to the sample; and making NMR measurements of the sample at the applied pressure using the NMR coil.

The method may comprise making NMR measurements of the sample at different pressures.

The method may comprise making NMR measurements as the pressure applied to the sample changes.

### BRIEF DESCRIPTION OF THE DRAWINGS

Various objects, features and advantages of the invention will be apparent from the following description of particular embodiments of the invention, as illustrated in the accompanying drawings. The drawings are not necessarily to scale, emphasis instead being placed upon illustrating the principles of various embodiments. Similar reference numerals indicate similar components.

FIG. 1 is a schematic cross-sectional diagram of the general design concepts of a first NMR apparatus.

FIG. 2 is a schematic cross-sectional diagram of the general design concepts of a second NMR apparatus.

FIG. 3 is a system schematic diagram of a NMR system.

### DETAILED DESCRIPTION

### Introduction

With reference to the figures, confined pressure chambers used for NMR measurements under extreme conditions are described. The systems are particularly applicable for conducting NMR measurements in a high pressure, high temperature environment.

The subject technology seeks to characterise samples at high pressures and/or high temperatures using NMR technology to in order to improve the accuracy and efficiency by which such measurements are made. More specifically, the subject technology may provide an inexpensive and simple structure configured to withstand the high temperatures and/or pressures required to make such measurements.

All terms used within this specification have definitions that are reasonably inferable from the drawings and description. In addition, the language used herein is to be interpreted to give as broad a meaning as is reasonable having consideration to the rationale of the subject invention as understood by one skilled in the art. It is also to be understood that prior art cited during prosecution of the subject patent application may not have been specifically identified prior to the drafting of the subject document and that various amendments may be introduced during prosecution that require amendment of terms to provide clarity to the distinctions between the subject invention and that prior art and that such amendments are reasonably inferable having consideration to the document as a whole and the rationale of the invention.

Various aspects of the invention will now be described with reference to the figures. For the purposes of illustration, components depicted in the figures are not necessarily drawn to scale. Instead, emphasis is placed on highlighting the various contributions of the components to the functionality of various aspects of the invention. A number of possible alternative features are introduced during the course of this description. It is to be understood that, according to the knowledge and judgment of persons skilled in the art, such alternative features may be substituted in various combinations to arrive at different embodiments of the present invention.

Within this specification embodiments have been described in a way which enables a clear and concise specification to be written, but it is intended and will be appreciated that embodiments may be variously combined or separated without parting from the invention. For example, it will be appreciated that all preferred features described herein may be applicable to all aspects of the invention described herein.

### Embodiment 1

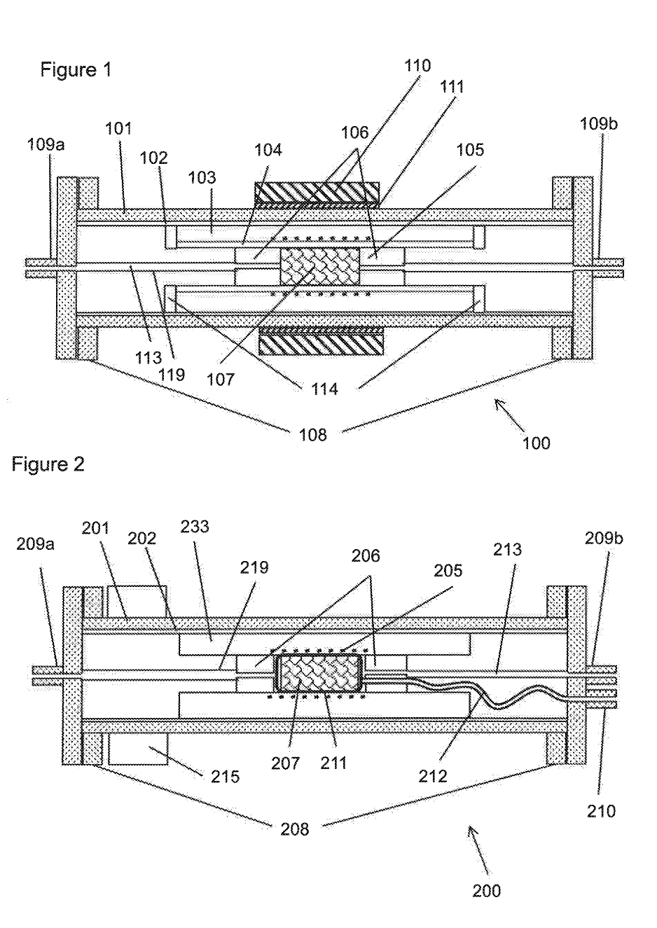

FIG. 1 depicts a cross-section of an NMR apparatus 100 comprising: a confined pressure chamber 101; a NMR coil 105 positioned within the chamber 101 and configured to receive a sample 107 in a sample position inside the NMR coil 105; and a pressure applicator configured to apply a pressure within the pressure chamber, thereby allowing NMR measurements to be made of a sample 107 in the sample position at the applied pressure using the NMR coil 105.

### Pressure Chamber

In this case, the confined pressure chamber 101 comprises a pipe section which is sealed at each end by two end-pieces. In this case, the pressure chamber comprises metallic titanium and/or titanium alloy, Hastelloy or Inconel. In embodiments with different temperature and pressure limits non-metallic pipes may be used. It will be appreciated that other materials may be used. The end-pieces are attached to each end of the pipe by means of connecting flanges (such as a standard pipe flange having bolt holes and threaded connector). It will be appreciated that there may be a gasket (e.g an O-ring) between the end-pieces and the flanges to improve the seal. It will be appreciated that the end-pieces may be connected and/or sealed by other appropriate connectors (e.g. the pipe and end-pieces may have corresponding screw threads). It will be appreciated that, in other embodiments, the confined pressure chamber may comprise a vessel with a lid; or two concave portions which when connected form the confined pressure chamber. In any case, the confined pressure chamber may be considered substantially sealed (apart from the allowing fluid in or out to control the pressure of the chamber).

In this case, the pressure chamber 101 is cylinder-shaped, and the NMR coil 105 axis is aligned with the axis of the pressure chamber. By using a pressure chamber 101 with a symmetry which corresponds to the NMR coil 105, the NMR field applied to the sample may be more consistent throughout the sample's bulk.

Generally, the pressure chamber 101 material is non-magnetic with mechanical characteristics enabling its use as a high pressure and/or high temperature chamber. The thickness of the pressure chamber 101 is primarily determined by the temperature and pressure performance requirements to safely contain the fluid 113. Typically, for a coring application, the pressure and temperature requirements of the outer layer are 100 to 10,000 psi (700 kPa to 70 MPa) or greater, and temperatures upwards of 400° F. (200° C.). The pressure which can be applied by certain embodiments may correspond to one or more of the following: 100 to 1,000 psi; 1,000 to 5,000 psi, 5,000 to 10,000 psi; and greater than 10,000 psi. The temperature which can be applied by certain embodiments may correspond to one or more of the following: 0 to 50° C.; 50 to 100° C., 100 to 150° C.; 150 to 200° C.; and greater than 200° C.

Using titanium or titanium alloys, Hastelloy and Inconel may enable a decreased thickness compared with other materials such as stainless steel (which may also be used). The lower thickness of the outer layer enables a larger sample space and coil size for a given pipe diameter. The lower thickness also means smaller outside diameter for a given pipe size, outside diameter determines the gap of the permanent magnet. Minimizing the magnet gap will decrease the magnet weight and the expensive material used to build it. The permanent magnet may be configured to create a homogenous magnetic field for the volume of the testing sample. The field strength may determine the NMR instrument frequency, so general the magnet field strength may be between 117 Gauss to 2348 Gauss (0.0117-0.2348 tesla) and corresponding frequency may be between 0.5 MHz to 10 MHz. The sample size determines the homogeneous area required and the homogeneous area determines the size and shape of the magnet. In this case, the pressure chamber 101 is placed between two poles of the permanent magnet. The U or C shape magnet may be used.

The pressure chamber 101 may comprise any non-magnetic metallic or non-metallic material, which is strong enough for given temperature and pressure conditions. A non-magnetic material for this application may be titanium alloy, hastelloy alloy, inconel alloy, beryllium copper alloy, Teflon, PEEK Torlon or even fiberglass reinforced plastic.

In this case, the pressure chamber 101 also comprises a conductive inner layer 102, the conductive inner layer 102 configured to constrain the magnetic field of the NMR coil and/or to shield the interior of the pressure chamber from external magnetic fields. The material of conductive inner layer 102 may have the same conductivity as, or greater conductivity than, the material of the NMR coil 105. In this case, both the NMR coil 105 and the conductive inner layer 102 comprise metallic copper. The conductive inner layer 102 may comprise the same non-magnetic material as the coil 105. The coil material is typically copper as described below. The purpose of conductive inner layer is to provide electromagnetic noise shielding from outside the pipe and maximizing the Q factor of the coil.

Q-factor, or quality factor, of the resonant circuitry that includes the coil 105 and serves as a sensor of the NMR signal is defined by the standard relation:

$$Q = 2 π \frac{Energy stored}{Energy dissipated per cycle}$$

Depending on the conditions of operations it can be advantageous to have a lower value of the Q-factor. In this case, the system can be used without conductive inner layer 102.

Lower Q-factor (5 to 10) is needed in order to reduce or minimize the acquisition time of the instrument, which is very important for measuring fast relaxing sample such as a fluid in very small pores (e.g. heavy bitumen fast relaxation components).

Higher Q-factor (above 20) may be particularly advantageous when filling factor is below 0.1 (the coil filling factor may be considered to be the proportion of the coil's sensitive volume which is occupied by the sample) or when water and oil percentage in the sample is less than 10% to get a reasonable high SNR (e.g. a signal to noise ratio of above 50). In other embodiments, if there is enough water or oil in the samples, the Q-factor may be lower (e.g. below 20 but above 5) in order to simplify the design (for example by omitting layer 2).

In a preferred embodiment, conductive inner layer 102 is a copper design on at least a portion of the inner surface of the pressure chamber 101. Generally, the conductive inner layer will improve the Q factor of the coil when the gap between conductive inner layer 102 and the coil 105 is limited. However, as noted above, the conductive inner layer 102 is not necessarily required.

### NMR Coil

In order to make the useable measuring area (sweet spot) long enough the NMR coil 105 length (shown in FIG. 2) may be at least two times the outer diameter of the NMR coil 105. In addition, the conductive inner layer 102 length may be at least four times the outer diameter of the NMR coil 105. These factors may make the measurable length at least as long as the outer diameter of the NMR coil 105.

In this case, the NMR apparatus comprises an NMR system configured to apply a CPMG (Car-Purcell-Meiboom-Gill) signal and/or a FID (Free Induction Decay) signal to the NMR coil. It will be appreciated that the NMR coil 105 may form part of the NMR system.

It will be appreciated that the NMR apparatus may comprise a controller (not shown), the controller configured to control one or more of the following: signals applied to the NMR coil 105; temperature applied to the sample 107; pressure applied to the sample 107; and flow rate of fluid through the sample 105.

The NMR apparatus may be configured to enable NMR measurements of the sample 107 to be made at different pressures.

The NMR apparatus may be configured to enable NMR measurements of the sample 107 to be made as the pressure applied to the sample 107 changes. For example, at low pressures (e.g. atmospheric) the NMR signals initially present in the sample 107 (which may include water and/or oil) may be identified by standard analysis. When the pressure applied to the sample is changed (e.g. increased), the signal from the original liquids may not be changed significantly compared with the change in the gas signals. This may be due to the fact that density of gas (i.e. amount of gas within the NMR sweet spot) may depend on the pressure, while the density of the liquid state does not. This may allow the gas signals to be distinguished (and identified and characterised).

The NMR controller may be configured to distinguish the state of various materials based on the relaxation time. For example, a gas in open space may relax slowly (typically, on the scale of tens to hundreds seconds), while an adsorbed gas may relax extremely quickly (in milliseconds or even microseconds range).

Fluid Flow within the Chamber

In this case, the pressure chamber comprises at least one duct 109a,b, the duct configured to allow a fluid 113 to be introduced into and/or removed from the pressure chamber 101. That is, each duct 109a,b may be one or more of an inlet and an outlet. In this case, the pressure applicator (not shown) comprises a pump configured to introduce fluid into the pressure chamber 101 via the inlet duct 109a to thereby pressurize the chamber and the sample. Fluid may be removed via outlet duct 109b. Fluid may be removed from the sample via outlet duct 109b. In this case, the fluid is directed between the ducts and the sample via conduits 119. It will be appreciated that one or more of these conduits may be omitted in some embodiments. It will be appreciated that the fluid 113 may be introduced into and/or removed from the pressure chamber whilst the sample 107 is in the sample position within the NMR coil 105. This may allow a series of measurements under different conditions to be made more quickly.

It will be appreciated that the chamber may be sealable. For example, the ducts may be closable which would prevent fluid flow from the inside and the outside of the pressure chamber.

In this case, the fluid 113 is configured to act as a conditioning fluid and as a flooding fluid. That is, the fluid is 113 configured to control the conditions of the sample (by controlling the temperature and/or pressure); and to interact directly with the sample (e.g. by directly contacting the sample to, for example, enter pores of the sample and/or absorb to the sample surface and/or flush fluids from the sample). In this case, the flooding fluid may be considered to be the conditioning fluid.

The NMR apparatus, in this case, further comprises a heater (not shown) configured to heat the sample. In this case, the heater comprises a fluid heater, the fluid heater configured to heat a fluid 113 to be introduced into the pressure chamber 101 via the duct 109a. The fluid 113 in turn heats the sample. It will be appreciated that the fluid 113 within the pressure chamber 101 may be heated in other ways. For example, in other embodiments, the NMR apparatus may comprise a heater configured to heat the outside of the pressure chamber 101 which in turn heats the sample by, for example, a combination of one or more of conduction, convection and radiative heat transfer. It will be appreciated that other embodiments may comprise a cooler, the cooler being configured to cool the sample and/or the fluid within the chamber. It will be appreciated that a heater may be configured to: measure the temperature of the chamber, sample and/or fluid; and or heat the chamber, sample and/or fluid to a predetermined temperature.

It will be appreciated that in within a confined pressure chamber 101 where fluid flow to and from the chamber 101 is restricted (e.g. the chamber is sealed by closing all the ducts), the temperature and the pressure within the chamber when sealed may be related. For example, heating a fluid within a sealed chamber may cause the pressure to rise, and cooling a fluid within a sealed chamber 101 may cause the pressure to fall.

In this case, the fluid 113 introduced into the chamber 101 comprises a gas such as steam, and/or hydrocarbon mixtures, and/or single hydrocarbons, and/or carbon dioxide. It will be appreciated that in other embodiments, the fluid 113 may comprise a liquid or a mixture (water or aqueous solutions and/or mixtures of hydrocarbons and/or carbon dioxide) of gas and liquid.

### Protective Layers

The NMR apparatus, in this embodiment, comprises two protective layers, including: a coil-chamber layer 103 comprising protective material positioned between the NMR coil and the inner surface of the pressure chamber; and a sample-coil layer 104 comprising protective material positioned between the NMR coil and the sample position.

Protective layers 103, 104 serve the purpose of protecting the coil 105 from flowing fluids 113 and/or to provide structural rigidity for coil 105. Protective layers materials are non-conductive materials having a high hardness enabling long-term performance in a high temperature, high pressure environment.

The sample-coil layer 104 may be configured to provide structural support for the coil. The sample-coil layer 104 may be configured to maintain the position of the sample 107 with respect to the coil 105.

The coil-chamber layer 103 may be configured to maintain the position of the coil 105 with respect to the chamber. The coil-chamber layer 103 may be configured to protect the outer surfaces of the coil.

The coil 105 may be supported on the sample-coil layer 104. For example, the sample-coil layer 104 may comprise one or more notches configured to receive the NMR coil thereby helping maintain the NMR coils shape. For example, during assembly, on the outside of sample-coil layer 104 the notches for the coil are pre machined and the depth of notch is deep enough to bury the coil 105 into the notches. The coil 105 is wrapped over sample-coil layer 104 and buried into the premade notches. The sample-coil layer 104 may then be slid into coil-chamber layer 105.

At least one of the protective layers (the coil-chamber layer and the sample-coil layer) may comprise polyether ether ketone (PEEK). PEEK is a non-metallic thermoplastic with good mechanical and chemical resistance properties that are retained to high temperatures. The Young's modulus is 3.6 GPa and its tensile strength 90 to 100 MPa. Some grades of PEEK have a useful operating temperature of up to 250° C. PEEK is highly resistant to thermal degradation as well as attack by both organic and aqueous environments. One or more of these properties allow PEEK to be used in high temperature and/or high pressure and/or corrosive environments. Other thermoplastics exist that may be used for the purpose of at least one of these protective layers include Teflon, or TORLON.

Protective layers 103, 104 may be held in place by one or more coil supporting members 114 (in this case in the form of a disk positioned at each end). The coil supporting members 114 may be configured to allow fluid flow within the chamber 101. The material for the coil supporting members 114 could be a suitable thermoplastic or even metal if it is positioned a distance of more than 1 coil diameter away axially from the coil 105 itself (e.g. so that the metal does not affect the magnetic field).

As shown in FIG. 1, the various components shown are an example of assembling the coil in cylindrical geometry and providing shielding from the environmental factors. Any other technology that will provide proper geometry of the coil and will incorporate protection of the coil from the environment may also be used. For example, epoxy resin may be used to build coil 105 assembly to replace the protective layers 103, 104. The coil 105 may be pre-machined with solid copper wire (thicker than AWG 14) so it can hold the shape after it is machined. A coil may be encased by a suitable proper epoxy resin (e.g. using resin curing or cross-linking technology) thereby providing the protective layers 103, 104.

In this case the sample 107 is held in the sample position by at least one spacer 106, each spacer 106 being positionable within the NMR core 105 beside the sample position. A said spacer 106 may be configured to restrict the presence of fluid 106 within the NMR core by, for example, inhibiting fluid which is not part of the sample (e.g. by interacting with the sample) being within the NMR core. In this way, the spacers help ensure that the NMR signal is dominated by the sample. The spacer in this case comprises a spacer channel, the spacer channel configured to allow fluid to reach the sample position. This may allow: the conditions (temperature and/or pressure) of the sample to be controlled via the fluid 113; and/or the sample to be flooded by a flooding fluid. The spacer may comprise an NMR-inactive material such as PEEK, Teflon, and/or TORLON.

### Protective Layers

In this case, the sample 107 comprises of a fluid mixture or a core sample obtained from the earth using a core drill. The sample may comprise a core sample from a conventional reservoir, a heavy oil reservoir, a bitumen reservoir or a tight formation (e.g. having porosity of 10% or less and permeability of 1 mD (˜1×10⁻³ (μm)²) or less). It will be appreciated that other porous samples may be used (e.g. from the mining, food and/or chemical industry) such as mining tailings, bones, powders, emulsions.

Having the coil within the pressure chamber may allow a more homogenous magnetic field in close proximity to the samples, a goal that cannot be achieved in the conventional designs (where the sample and sample container are both located within the NMR coil). This in turn allows for smaller echo space echo space (time) that can then be used to detect faster relaxing components. Small pore sizes characteristic of tight formations lead to fast relaxation times which may make the signal not measurable by other methods. Having the coil inside the pressure chamber may increase the coil filling factor closer to 1.0 (the coil filling factor may be considered to be the proportion of the coil's sensitive volume which is occupied by the sample). Smaller diameter of the coil means lower inductance of the coil, which will make it easier to achieve smaller echo space time. How small the echo space time can achieve will determine how fast the relaxation components can be detected.

As shown in FIG. 1, outside the pressure chamber 101, the magnet 110 is installed outside the magnet lining layer 111. The magnet lining layer may isolate the heating transfer between hot pressure chamber 101 and magnet 110. The material of magnet lining layer may be any nonmagnetic material with very low heat conductivity, such as aerogel. The magnet may be a U or C-shaped magnet.

### Sample

In this case the sample may be a core sample. A core sample may be one or more of: a full-diameter core, an oriented core, a native state core and a sidewall core.

A core may be 1 to 6 inches (˜2.5-15 cm) in diameter.

Native state cores may be enclosed by being, for example, bagged or encircled by a rubber sleeve as the sample is drilled in order to retain the fluids in the core under reservoir conditions. The rubber seal may form a flexible sample compartment.

Sidewall cores may be approximately 1 inch (2.5 cm) in diameter and approximately 2 inches (5 cm) long.

One type of sidewall coring may be performed using a percussion sidewall coring tool which is lowered into the wellbore. The instrument contains a number of small coring tubes (e.g. 20 to 30) called bullets that have explosive charges behind them. The detonation of these bullets launches them into the sides of the wellbore to take the samples. The bullets are connected to the instrument via wires, and may be retrieved when the percussion sidewall coring tool is raised.

Another method of obtaining sidewall core samples is to use a rotary sidewall coring instrument into the well. The rotary sidewall coring instrument may obtain a number of different samples throughout the well, which may be separated from each other via discs within the tool.

### Embodiment 2

FIG. 2 depicts a second embodiment of an NMR apparatus with a sample 207 (which in this case is between 1 cm (0.4 inches) and 10 cm (4 inches) in length) in the sample position. The second embodiment is similar to the first embodiment, and it will be appreciated that features of one embodiment may be used in conjunction with another embodiment. Only the top and bottom of the NMR coil 205 is shown in FIG. 2 for clarity.

The second embodiment also comprises: a confined pressure chamber 201 (which in this case is cylinder-shaped and comprises titanium alloy); a NMR coil 205 positioned within the chamber 201 and configured to receive a sample in a sample position inside the NMR coil; and a pressure applicator (not shown) configured to apply a pressure within the pressure chamber 201, thereby allowing NMR measurements to be made of a sample in the sample position at the applied pressure using the NMR coil. It will be appreciated that a pressure applicator may be configured: to measure the pressure of the chamber; and/or to apply a predetermined pressure to the chamber. The pressure applicator, in this case, comprises a pump (not shown) configured to introduce fluid into the pressure chamber via an inlet duct 209a to thereby pressurize the chamber and the sample. Fluid may be removed from the sample via outlet duct 209b. In this case, the conditioning fluid is directed between the ducts and the sample via conditioning conduits 219. It will be appreciated that one or more of these conditioning conduits may be omitted in some embodiments.

In this case, outside the pressure chamber 201, a magnet (not shown) is installed. The magnet may be, for example, a U or C-shaped magnet.

In this case, the apparatus also comprises a heater 215 configured to heat the sample. However, unlike the previous embodiment, in this case the heater 215 is configured to heat the chamber wall. This heat is then transmitted through the chamber wall which heats the fluid 213 within the chamber which in turn heats the sample. It will be appreciated that, in other embodiments, a heater may be placed inside the chamber. It will be appreciated that a heater may also act as a cooler, the cooler being configured to cool the sample.

Like the previous embodiment, the present embodiment comprises an conductive inner layer 202 (which in this case is a coating of, e.g., metallic copper), the conductive inner layer configured to constrain the magnetic field of the NMR coil and/or to shield the interior of the pressure chamber from external magnetic fields. It will be appreciated that in some embodiments, this conductive inner layer may be omitted.

In this case, the NMR apparatus comprises a protective layer 233 comprising: protective material positioned between the NMR coil and the inner surface of the pressure chamber; and between the NMR coil and the sample position. In the previous case, this protection was performed by having two separate protective layers of PEEK. In this case, there is one protective layer 233 protecting both the inside and the outside of the coil.

In this case, epoxy resin is used to build coil 205 assembly and to provide the protective layer 233. The coil 205, in this case, is pre-machined with solid copper wire (e.g. thicker than AWG 14) so it can hold the shape after it is machined. The coil 205 may be encased by a suitable proper epoxy resin (e.g. using resin curing or cross-linking technology) thereby providing the protective layer 233.

In this case, the NMR apparatus comprises at least one spacer positioned within the NMR core beside the sample position, the at least one spacer configured to restrict the presence of fluid within the NMR core. It will be appreciated that, although the spacer may restrict the presence of fluid within the NMR core by, for example, displacing the fluid, the spacer may be configured to allow fluid flow to and from the sample.

It will be appreciated that the NMR apparatus may be connectable to, form part of, or comprise, a NMR system configured to apply a CPMG (Car-Purcell-Meiboom-Gill) signal and/or a FID (Free induction decay) signal to the NMR coil.

It will be appreciated that the NMR apparatus may be connectable to, or comprise, a controller. The controller may comprise a processor; and memory having computer program code. The processor, in this case, may be configured to run the computer program code stored on the memory in order to control the NMR system. The controller may be configured to control one or more of the following: signals applied to the NMR coil; temperature applied to the sample; pressure applied to the sample; and flow rate of fluid through the sample.

A processor may comprise one or more of: a central processing unit and a microprocessor (e.g. an application-specific integrated circuit (ASIC), an application-specific instruction set processor (ASIP), a graphics processing unit (GPU), a digital signal processor (DSP)). Memory may comprise volatile (e.g. RAM) and/or non-volatile memory (e.g. hard drive, flash memory, CD, DVD or other disc). A computer program may be stored in a non-transitory medium such as a CD or hard-disk.

In this case, the apparatus comprises a comprises a flexible sample compartment 211 configured: to contain the sample in the sample position; restrict flooding-fluid flow away from the sample; and/or allow pressure (and possibly heat) to be transmitted from a conditioning fluid to the sample, the conditioning fluid being outside the flexible sample compartment. That is, unlike the first embodiment, where a single fluid acted as a conditioning fluid (controlling temperature and/or pressure) and as a flooding fluid (interacting with the sample directly), in this case the flooding fluid is kept separate from the conditioning fluid 213 by the sample compartment. It will be appreciated that the sample compartment may impermeable to the flooding fluid and/or the conditioning fluid.

The flooding fluid in this case comprises a liquid whereas the conditioning fluid 213 comprises a gas (e.g. nitrogen or air). In this case, the flooding fluid comprise comprises deuterated water. Using deuterated water allows non-aqueous signals to dominate the NMR spectra. Other flooding fluids may include other deuterated or non-deuterated materials such as acetone, alkanes, benzene. Flooding fluids may comprise labelled solvents having, for example, deuterium and/or carbon-13.

The flexible sample compartment 211 may be fitted (e.g. in size and/or shape) to the sample. For example, the flexible sample compartment 211 may comprise a resilient material which is stretched to accommodate (e.g. contain) the sample. In this way, the flooding fluid within the flexible sample compartment 211 is in direct contact with the sample which reduces the signal from the flooding fluid which is not interacting with the sample 207. For example, the sample may be shrink-wrapped in a resilient sample compartment.

In this case, the NMR apparatus 200 further comprises at least one flooding conduit 212, the flooding conduit 212 configured to enable flooding fluid to flow between the outside of the pressure chamber 201 and the sample 207. This allows the flooding fluid to be changed without opening the chamber. The flooding fluid in this case is flows between the outside of the chamber and the inside of the chamber via a duct 210. That is, in this case the pressure chamber comprises two ducts, each duct configured to allow a fluid to be introduced into and/or removed from the pressure chamber. The flooding duct 210 facilitates the introduction and removal of flooding fluid; and the conditioning ducts 209a,b facilitates the introduction and removal of conditioning fluid. It will be appreciated that, in other embodiments, there may be an inlet duct and a corresponding outlet duct for one fluid (e.g. in order to allow the fluid to be recycled continuously).

It will be appreciated that the chamber may be sealable (e.g. such that fluid flow is prevented between the inside and the outside of the pressure chamber). For example, the ducts may be closable which would prevent fluid flow between the inside and the outside of the pressure chamber.

It will be appreciated that other embodiments may comprise a sample compartment but not a flooding conduit. For example, the sample may be placed in a sealed sample compartment with flooding fluid before being placed in the NMR apparatus. In this way, the pressure and temperature of the sample may be adjusted using the conditioning fluid even though the flooding fluid may not be changed.

The at least one flooding conduit and the sample compartment in this case may be made of a NMR inactive material (a wide variety of plastics).

### NMR System

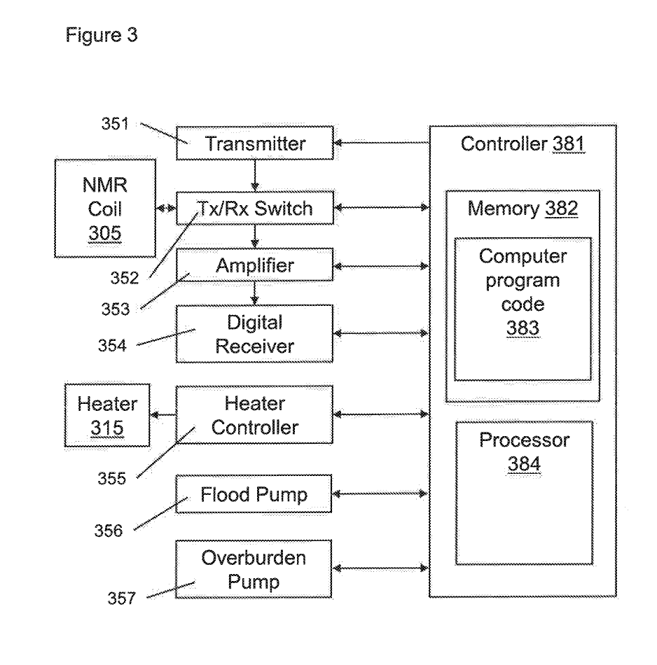

It will be appreciated that the embodiments described above (and other embodiments) may form part of an NMR system. A schematic of an embodiment of an NMR system is shown in FIG. 3.

In this case the NMR system is controlled by a controller 381 comprising a processor 384; and memory 382 having computer program code. The processor 384, in this case, is configured to run the computer program code stored on the memory in order to control the NMR system.

In this case, the controller is configured to control various systems including a transmitter 351; transmission/reception switch 352 for controlling whether the signal generated by the transmitter is sent to the NMR coil 305 and/or how the response is received from the NMR coil 305; an amplifier 353 configured to process the received response signal; a digital receiver 354 configured to receive the response; a heater controller 355 configured to control the heater 315 (and so control the temperature in the chamber); a flood pump 356 configured to flood the sample with fluid; and an overburden pump 357 configured to apply a pressure inside the chamber. It will be appreciated that some embodiments may not have one or more of these features.

Although the present invention has been described and illustrated with respect to preferred embodiments and preferred uses thereof, it is not to be so limited since modifications and changes can be made therein which are within the full, intended scope of the invention as understood by those skilled in the art.

1. An NMR apparatus comprising:
a confined pressure chamber;
a NMR coil positioned within the chamber and configured to receive a sample in a sample position inside the NMR coil; and
a pressure applicator configured to apply a pressure within the pressure chamber, thereby allowing NMR measurements to be made of a sample in the sample position at the applied pressure using the NMR coil.

2. The NMR apparatus of claim 1, wherein the NMR apparatus comprises one or more of:
a heater, the heater being configured to heat the sample; and
a cooler, the cooler being configured to cool the sample.

3. The NMR apparatus of claim 1, wherein the pressure chamber comprises at least one duct, the duct configured to allow a fluid to be introduced into and/or removed from the pressure chamber.

4. The NMR apparatus of claim 1, wherein the pressure applicator comprises a pump configured to introduce fluid into the pressure chamber via a duct to thereby pressurize the chamber and the sample.

5. The NMR apparatus of claim 1, wherein the NMR apparatus comprises a fluid heater, the fluid heater configured to heat a fluid to be introduced into the pressure chamber via a duct.

6. The NMR apparatus of claim 5, wherein the fluid comprises one or more of: a gas; a liquid; and deuterated water.

7. The NMR apparatus of claim 1, wherein the pressure chamber is cylinder-shaped and wherein the NMR coil axis is aligned with the axis of the pressure chamber.

8. The NMR apparatus of claim 1, wherein the pressure chamber comprises a conductive inner layer, the conductive inner layer configured to constrain the magnetic field of the NMR coil and to shield the interior of the pressure chamber from external magnetic fields.

9. The NMR apparatus of claim 8, wherein the conductive inner layer comprises metallic copper.

10. The NMR apparatus of claim 1, wherein the NMR apparatus comprises one or more protective layers, the one or more protective layers comprising one or more of:
protective material positioned between the NMR coil and the inner surface of the pressure chamber; and
protective material positioned between the NMR coil and the sample position.

11. The NMR apparatus of claim 1, wherein the NMR apparatus comprises at least one spacer positioned within the NMR core beside the sample position, the at least one spacer configured to restrict the presence of fluid within the NMR core.

12. The NMR apparatus of claim 11, wherein the spacer is configured to allow fluid to reach the sample position.

13. The NMR apparatus of claim 1, wherein the length of the sample in the direction of the NMR coil axis is greater than about 1 cm (0.4 inches).

14. The NMR apparatus of claim 1, wherein the NMR apparatus comprises a controller, the controller configured to control one or more of the following:
signals applied to the NMR coil;
temperature applied to the sample;
pressure applied to the sample; and
flow rate of fluid through the sample.

15. The NMR apparatus of claim 1, wherein the pressure chamber comprises metallic titanium.

16. The NMR apparatus of claim 1, wherein the NMR apparatus comprises a flexible sample compartment configured:
to contain the sample in the sample position;
restrict flooding-fluid flow away from the sample; and
allow pressure to be transmitted from a conditioning fluid to the sample, the conditioning fluid being outside the flexible sample compartment.

17. The NMR apparatus of claim 16, wherein the NMR apparatus comprises at least one flooding conduit, the flooding conduit configured to enable flooding fluid to flow between the outside of the pressure chamber and the sample.

18. A method, the method comprising:
positioning a sample within an NMR coil, the NMR coil being positioned within a confined pressure chamber;
applying a pressure within the pressure chamber, thereby applying a pressure to the sample;
making NMR measurements of the sample at the applied pressure using the NMR coil.

19. The method of claim 18, wherein the method comprises making NMR measurements of the sample at different pressures.

20. The method of claim 18, wherein the method comprises making NMR measurements as the pressure applied to the sample changes.
